(19) United States
(12) Patent Application Publication
(10) Pub. No.: US 2025/0308834 A1
(43) Pub. Date: Oct. 2, 2025

(54) ION MILLING DEVICE AND ION MILLING METHOD

(71) Applicant: Hitachi High-Tech Corporation, Minato-ku, Tokyo (JP)

(72) Inventors: Kengo ASAI, Tokyo (JP); Hisayuki TAKASU, Tokyo (JP)

(21) Appl. No.: 18/864,289

(22) PCT Filed: Jul. 28, 2022
(86) PCT No.: PCT/JP2022/029195

§ 371 Date: Nov. 8, 2024

(51) Int. Cl. H01J 37/08; H01J 37/14; H01J 37/20; H01J 37/305

(52) U.S. Cl. CPC H01J 37/08; H01J 37/14; H01J 37/20; H01J 37/3053

(57) ABSTRACT

An ion milling device and method to increase milling speed and lengthen a maintenance cycle, including an ion gun including a first cathode and a second cathode which face each other, the second cathode having an ion beam extraction hole; an anode provided between the first cathode and the second cathode in a state of being electrically insulated from the first cathode and the second cathode; an ionization chamber that is surrounded by the first cathode, the second cathode, and the anode and to which a gas is supplied; and a magnet. The anode has a cylindrical shape with longitudinal direction along a central axis, and has a first protrusion formed on an inner wall in contact with the ionization chamber toward the central axis in a range from a position equidistant from both end portions of the anode to the end portion facing the first cathode.

### TECHNICAL FIELD

The present invention relates to an ion milling device that prepares a sample to be observed by using a scanning electron microscope, a transmission electron microscope, or the like, and an ion milling method using the same.

### BACKGROUND ART

An ion milling method is a processing method in which an accelerated ion is made to collide with a sample and the sample is cut by utilizing a sputtering phenomenon in which the ion flicks an atom and a molecule. In the sample to be processed, a mask serving as a shielding plate against an ion beam is placed on an upper surface, and a protruding portion from an end surface of the mask is sputtered, whereby a flat and smooth cross section can be obtained. This method is used for a metal, a glass, a ceramic, an electronic component, a composite material, and the like.

For example, in a case of the electronic component, this method is used for applications such as evaluation for an internal structure, a cross-sectional shape, and a film thickness, and analysis for a crystal state, a failure and a cross section of a foreign substance. This method is also utilized as a cross section sample preparation method for acquiring a morphological image, a sample composition image, a channeling image, X-ray analysis, crystal orientation analysis, and the like by using various types of measurement devices including a scanning electron microscope.

Some of such ion milling devices use a small-sized penning discharge type ion gun having a simple configuration as an ion gun. A basic structure of the penning discharge type ion gun includes a gas supply mechanism that supplies a gas into the ion gun, an anode that is provided inside the ion gun and to which a positive voltage is applied, a cathode that generates a potential difference between the anode and the cathode, and a magnet. A penning type ion gun is characterized in that a high milling speed due to high energy of the ion beam can be obtained.

PTL 1 discloses a method of maintaining a current value of an ion beam emitted from an ion gun at a maximum value in order to maintain a high milling speed.

PTL 2 discloses a method in which, in order to increase the amount of ions emitted from an ion gun, a magnet having a specific magnetic flux density is used to ideally form a profile of an ion beam, thereby controlling a region of an ionization chamber within a range in which the ions can be emitted from the ion gun without colliding with a peripheral portion of an acceleration electrode outlet hole.

### CITATION LIST

### Patent Literature

PTL 1: JP2007-48588A

PTL 2: JP2016-31870A

### SUMMARY OF INVENTION

### Technical Problem

With the progress of the ion milling device in recent years, the market thereof is widely expanded. Therefore, there is a demand for development of an ion gun that has a higher milling speed than an ion gun in the related art depending on an application field. Examples include analysis for three-dimensional mounting using a through silicon via (TSV) that is attracting attention in the semiconductor field. There is a problem that, in a case of processing a laminated thick film sample, the processing takes a long time at a milling speed in the related art, and an operation rate of the device is reduced. In addition, the penning discharge type ion gun has a problem, due to a mechanism thereof, that a part of ions generated inside the ion gun are directed to the cathode provided to face a beam emission port and collide with the cathode, causing damage to the cathode and reducing processing stability.

### Solution to Problem

An ion milling device according to an embodiment of the invention includes: an ion gun that includes an ion generation unit and a gas supply mechanism configured to supply a gas to the ion generation unit, that accelerates an ion generated in the ion generation unit, and that emits the accelerated ion as an ion beam; and a sample stage on which a sample to be irradiated with the ion beam from the ion gun is placed, in which the ion generation unit of the ion gun includes a first cathode having a disk shape and a second cathode having a disk shape provided to face each other, the second cathode being provided with an ion beam extraction hole, an anode provided between the first cathode and the second cathode in a state of being electrically insulated from the first cathode and the second cathode, an ionization chamber that is surrounded by the first cathode, the second cathode, and the anode and to which the gas is supplied from the gas supply mechanism, and a magnet configured to generate a magnetic field in the ionization chamber, and the anode has a cylindrical shape whose longitudinal direction is a direction along a central axis of the ion generation unit, and has a first protrusion formed on an inner wall in contact with the ionization chamber toward the central axis in a range from a position equidistant from both end portions of the anode to the end portion facing the first cathode.

### Advantageous Effects of Invention

A milling speed of an ion milling device can be increased, and a maintenance cycle can be lengthened. Other problems and novel features will become apparent from description of the present specification and the accompanying drawings.

### BRIEF DESCRIPTION OF DRAWINGS

FIG. 1 is a drawing illustrating a configuration of an ion milling device.

FIG. 2 is a diagram illustrating a cross section of an ion gun and a configuration of a related peripheral portion according to a comparative embodiment.

FIG. 3 is a diagram illustrating a cross section of an ion gun and a configuration of a related peripheral portion according to a comparative embodiment.

FIG. 4 is a diagram illustrating electron trajectory analysis results and ion trajectory analysis results of the ion guns according to the comparative embodiments.

FIG. 5 is a diagram illustrating shapes of beam marks obtained by the ion guns according to the comparative embodiments.

FIG. 6 is a diagram illustrating a cross section of an ion gun and a configuration of a related peripheral portion according to Embodiment 1.

FIG. 7 is a diagram illustrating a cross section of an ion gun and a configuration of a related peripheral portion according to Embodiment 2.

FIG. 8 is a diagram illustrating electron trajectory analysis results and ion trajectory analysis results of the ion guns according to the embodiments.

FIG. 9 is a diagram illustrating a shape of an anode according to Embodiment 1.

FIG. 10 is a diagram illustrating a shape of the anode according to Embodiment 1.

FIG. 11 is a diagram illustrating a cross section of an ion gun and a configuration of a related peripheral portion according to Modification 1.

FIG. 12 is a diagram illustrating a cross section of an ion gun and a configuration of a related peripheral portion according to Modification 2.

FIG. 13 is a diagram illustrating a cross section of an ion gun and a configuration of a related peripheral portion according to Modification 3.

### DESCRIPTION OF EMBODIMENTS

Hereinafter, preferred embodiments of the invention are described with reference to the drawings.

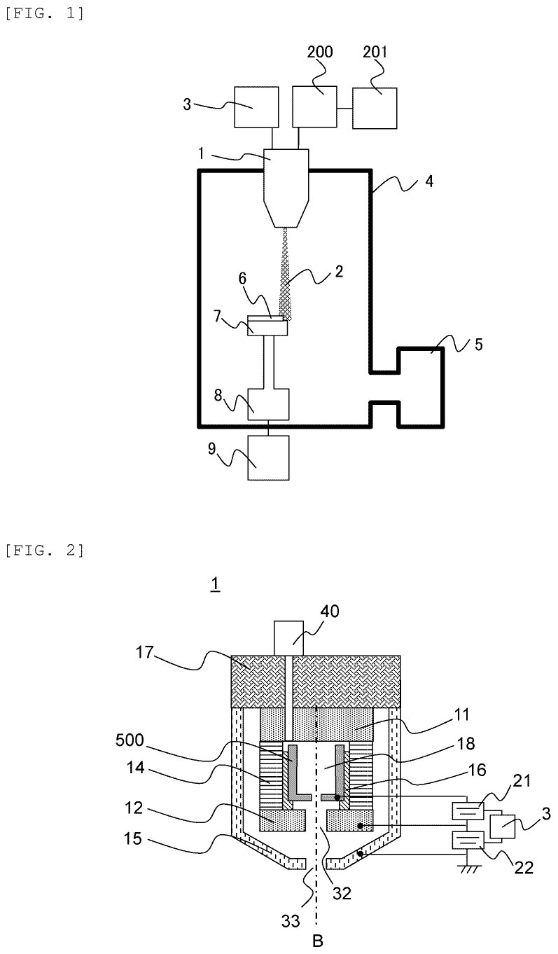

FIG. 1 is a drawing illustrating a configuration of an ion milling device. A so-called penning discharge type ion gun 1 or an ion gun 1 having a similar shape includes therein an element required for generating an ion, and forms an irradiation system for irradiating a sample 6 with an ion beam 2 that is unfocused. A gas source 201 is connected to the ion gun 1 via a gas supply mechanism 200, and a gas flow rate controlled by a gas supply mechanism 40 is supplied into an ionization chamber of the ion gun 1. The irradiation with the ion beam 2 and an ion beam current thereof are controlled by an ion gun controller 3. A vacuum chamber 4 is controlled to an atmospheric pressure or a vacuum by a vacuum exhaust system 5. The sample 6 is held on a sample stand 7, and the sample stand 7 is held by a sample stage 8. The sample stage 8 can be pulled out of the vacuum chamber 4 when the vacuum chamber 4 is opened to the atmosphere, and includes a mechanism element for inclining the sample 6 at any angle with respect to an optical axis of the ion beam 2. A sample stage driving unit 9 can swing the sample stage 8 to left and right, and can control a speed of the sample stage 8.

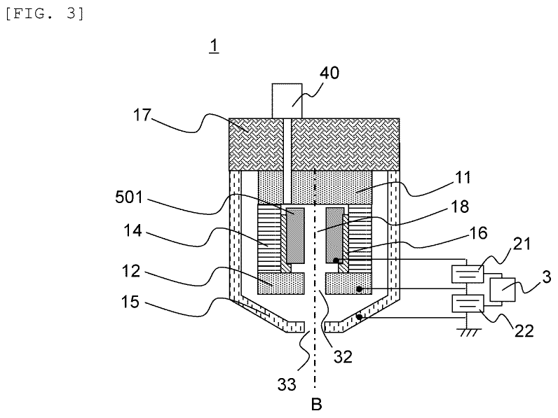

FIG. 2 is a diagram illustrating a cross section of an ion gun and a configuration of a related peripheral portion according to a comparative embodiment. The ion gun in FIG. 2 is an example in which an anode having a shape schematically disclosed in PTL 1 is provided as an anode 500. First, a structure and an operation of the penning discharge type ion gun are described by taking the ion gun illustrated in FIG. 2 as an example.

A first cathode 11 is made of a magnetic material having conductivity such as pure iron and formed in a disk shape, and is provided with a hole for introducing a gas into an ionization chamber 18 and a hole through which an anode pin (not illustrated), which is used for supplying power to the anode 500, passes. A magnet 14 is formed in a cylindrical shape, and one end of the magnet 14 is connected to the first cathode 11 made of the magnetic material. A second cathode 12 is made of a magnetic material having conductivity such as pure iron and formed in a disk shape, and is provided with a cathode outlet hole 32 serving as an ion beam extraction hole in a center portion. A diameter of the cathode outlet hole 32 is, for example, 5 mm. The second cathode 12 is connected to the other end of the magnet 14. The first cathode 11, the magnet 14, and the second cathode 12 form a magnetic path, thereby generating a magnetic field within the ion gun 1. The magnet 14 is preferably a samarium-cobalt magnet, which is a permanent magnet. The magnet 14 is not limited to the permanent magnet, and an electromagnet may be used as the magnet 14 to generate the magnetic field. An insulator 16, which is formed in a cylindrical shape, is provided inside the magnet 14, and an outer surface of the insulator 16 is in contact with an inner surface of the magnet 14. The insulator 16 is made of a non-magnetic material having an electrical insulation property such as a ceramic. The anode 500 is fitted inside the insulator 16, an outer surface of the anode 500 is in contact with an inner surface of the insulator 16, and an inner surface of the anode 500 faces the ionization chamber 18. The anode 500 is made of a non-magnetic material having conductivity such as aluminum and is formed in a cylindrical shape. The anode 500 is electrically insulated from the first cathode 11, the second cathode 12, and the magnet 14 by the insulator 16. An acceleration electrode 15 is made of a non-magnetic material having conductivity such as a stainless steel and is formed in a cylindrical shape, and is provided with an acceleration electrode outlet hole 33 serving as the ion beam extraction hole in a center portion. A diameter of the acceleration electrode outlet hole 33 is, for example, 5 mm. The acceleration electrode 15, which is kept at a ground potential, is fixed to a peripheral portion of an ion gun base 17 to surround the first cathode 11, the second cathode 12, and the magnet 14. The ion gun base 17 and the first cathode 11 are provided with a hole through which, for example, an Ar gas introduced from the gas supply mechanism 40 is introduced into the ionization chamber 18. The gas introduced into the ionization chamber 18 is typically an Ar gas, but other inert gases may also be introduced.

The first cathode 11, the second cathode 12, the magnet 14, a cathode, and the ionization chamber 18 defined by these parts, which generate an electric field and a magnetic field for generating an ion, in the ion gun are collectively referred to as an ion generation unit. The ion generation unit and the acceleration electrode are axisymmetric about a central axis B of the ion generation unit.

The Ar gas introduced into the ionization chamber 18 is brought into a state where an appropriate gas partial pressure is maintained, a discharge voltage of about 0 kV to 4 kV is applied between the first cathode 11 as well as the second cathode 12 and the anode 500 by a discharge power supply 21, and glow discharge is performed to generate an Ar ion. At this time, an electron generated by the discharge can be rotated by the magnet 14 to lengthen an electron trajectory and improve a discharge efficiency. An acceleration voltage of about 0 kV to 10 kV (or more) is applied between the second cathode 12 and the acceleration electrode 15 by an acceleration power supply 22 to accelerate the Ar ion, whereby the accelerated ion beam is emitted to the outside of the ion gun. The magnet 14 and the first cathode 11 are electrically connected to the second cathode 12 and kept at a same potential as the second cathode 12. By such voltage application, electrons are emitted from a surface of the first cathode 11 and a surface of the second cathode 12, and the emitted electrons are accelerated toward the anode 500. At this time, a trajectory of the electrons emitted from the surface of the first cathode 11 and the surface of the second cathode 12 are bent, in the ionization chamber 18, by the magnetic field formed by the first cathode 11, the second cathode 12, and the magnet 14, and the electrons perform a swirling motion. When the electrons swirling in the ionization chamber 18 collide with the introduced Ar gas, the Ar gas subjected to the collision is ionized, and cations are generated in the ionization chamber 18.

A part of the cations generated in the ionization chamber 18 pass through the cathode outlet hole 32 in the second cathode 12, and are accelerated by the acceleration electrode 15, the accelerated cations are emitted to the outside of the ion gun 1 through the acceleration electrode outlet hole 33 in the acceleration electrode 15, and a sample is processed by using an ion beam including the cations. On the other hand, another part of the cations generated in the ionization chamber 18 are attracted toward the first cathode 11 and collide with the first cathode 11, causing damage to the first cathode 11.

As described above, the anode 500 according to this comparative embodiment has the shape disclosed in PTL 1. That is, the anode 500 has a cylindrical shape whose longitudinal direction is a direction along the central axis B of the ion generation unit, and has a protrusion formed on an inner surface of the anode 500 in contact with the ionization chamber 18 toward the central axis B at an end portion facing the second cathode 12, and an inner diameter of a portion where the protrusion is formed is narrowed.

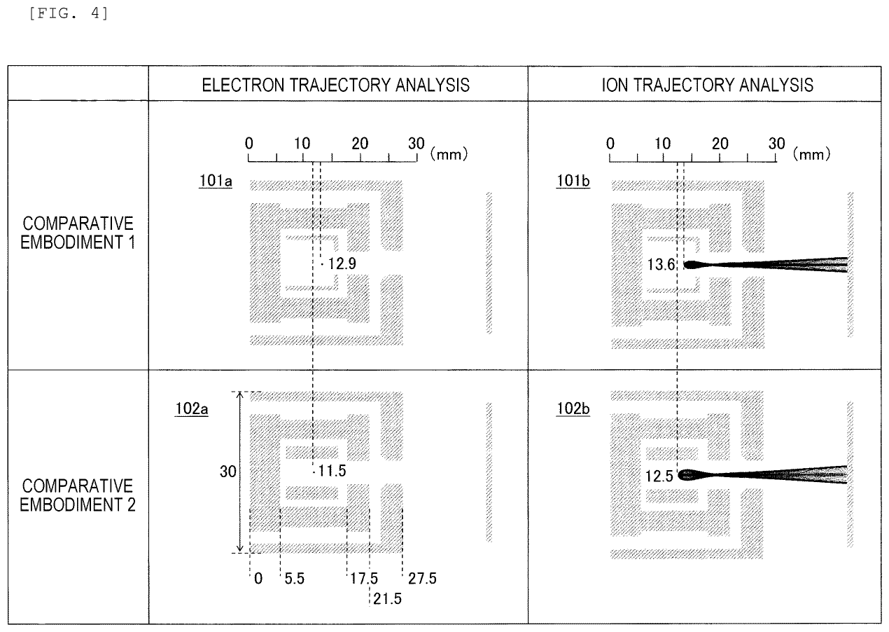

FIG. 3 is a diagram illustrating a cross section of an ion gun and a configuration of a related peripheral portion according to another comparative embodiment. The ion gun in FIG. 3 is an example in which an anode having a shape disclosed in PTL 2 is provided as an anode 501. That is, the anode 501 is made of a non-magnetic material having conductivity such as aluminum and is formed in a cylindrical shape. The anode 501 does not include the protrusion as in Comparative Embodiment 1, but has a flat inner wall with respect to the central axis B of the ion generation unit. In this comparative embodiment and embodiments described later, the structure and operation of the ion gun are the same as those in FIG. 2, and therefore, repeated description is omitted.

FIG. 4 is a diagram illustrating electron trajectory analysis results and ion trajectory analysis results of the ion guns according to the comparative embodiments. Comparative Embodiment 1 is an ion gun having the anode shape illustrated in FIG. 2, and analysis results of Comparative Embodiment 1 are analysis results 101a and 101b. Comparative Embodiment 2 is an ion gun having the anode shape illustrated in FIG. 3, and analysis results of Comparative Embodiment 2 are analysis results 102a and 102b. For comparison, a simulation is performed with a same configuration except for the anode shape. Sizes of the ion gun used in the simulation are illustrated in the analysis result 102a.

The electron trajectory in the ion gun is obtained by calculating an electric field and a magnetic field generated inside the ion gun. An electron concentration point where electrons generated inside the ion gun are concentrated at a higher concentration is found based on electron trajectory analysis. It is illustrated that the electron concentration point is located at a distance of 12.9 mm from a bottom surface of a first cathode in the analysis result 101a according to Comparative Embodiment 1, and is located at a distance of 11.5 mm from the bottom surface of the first cathode in the analysis result 102a according to Comparative Embodiment 2. The bottom surface of the first cathode refers to a surface of the first cathode 11 facing a surface of the first cathode 11 in contact with the ionization chamber 18. FIG. 4 also illustrates a coordinate system along the central axis B of the ion generation unit with the bottom surface of the first cathode as a reference position (0 mm).

An ion trajectory in the ion gun is also obtained by calculating the electric field and the magnetic field generated inside the ion gun. In ion trajectory analysis, a region is illustrated in which 100% of ions generated inside the ion gun are emitted through the acceleration electrode outlet hole 33. The analysis result 101b according to Comparative Embodiment 1 shows that ions generated in a region closer to the second cathode 12 at a distance of 13.6 mm from the bottom surface of the first cathode are emitted to the outside, and the analysis result 102b according to Comparative Embodiment 2 shows that ions generated in a region closer to the second cathode 12 at a distance of 12.5 mm from the bottom surface of the first cathode are emitted to the outside. This means that ions generated in a region closer to the first cathode 11 at a distance of 13.6 mm from the bottom surface of the first cathode in Comparative Embodiment 1, and ions generated in a region closer to the first cathode 11 at a distance of 12.5 mm from the bottom surface of the first cathode in Comparative Embodiment 2 mainly collide with the inside of the ion gun, causing damage to the cathode and the like.

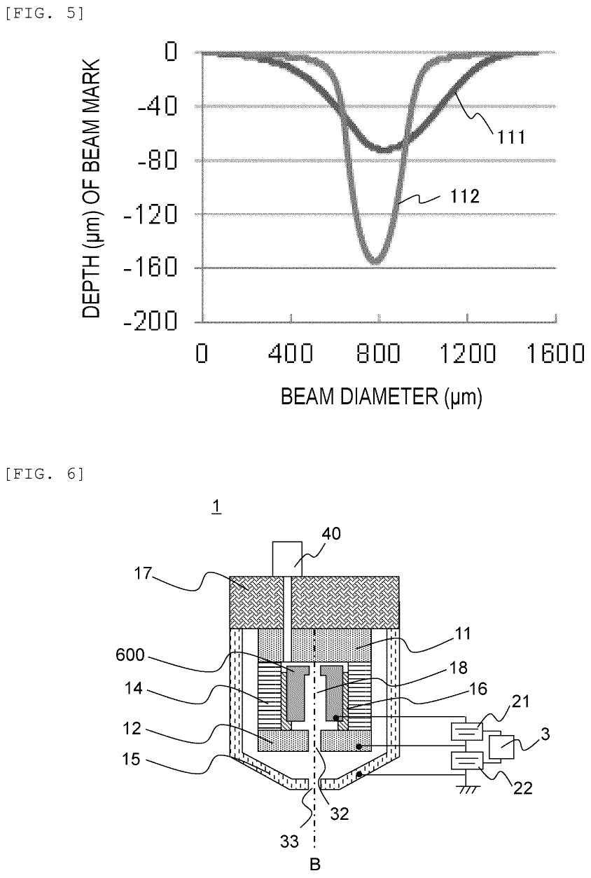

FIG. 5 is a diagram illustrating shapes of beam marks formed on the sample when processing is performed under the same condition by ion milling devices s including the ion guns according to the comparative embodiments. A beam mark 111 has a shape of the beam mark in Comparative Embodiment 1, and has a depth of about 75 μm. A beam mark 112 has a shape of the beam mark in Comparative Embodiment 2, and has a depth of about 155 um. Thus, in Comparative Embodiment 2, a processing depth of about twice that of Comparative Embodiment 1 is obtained.

From the above, in Comparative Embodiment 2, the electron concentration point is shifted toward the first cathode 11 by 1.4 mm (from 12.9 mm to 11.5 mm) than in Comparative Embodiment 1, and a deepest portion of an ion emission position is shifted toward the first cathode 11 by 1.1 mm (from 13.6 mm to 12.5 mm) than in Comparative Embodiment 1. Accordingly, the processing depth is about twice that of Comparative Embodiment 1. The ions generated by the collision of the electrons and the argon gas are generated at a high concentration near the electron concentration point, and therefore, it is considered that, in Comparative Embodiment 2, the electron concentration point and the ion emission position are both shifted toward the first cathode 11, resulting in a significantly larger amount of ions being emitted from an ion emission range that is larger than that in Comparative Embodiment 1.

Here, since the anode is made of the non-magnetic material, there is no difference in magnetic field generated in the ion generation unit between Comparative Embodiment 1 and Comparative Embodiment 2. Therefore, the above change is caused by the electric field that is changed due to the anode shape. The inner wall of the anode in Comparative Embodiment 2 is flat with respect to the central axis B of the ion generation unit, whereas the anode in Comparative Embodiment 1 generates a strong potential gradient in a direction of the central axis B within the ionization chamber 18 by the protrusion formed at the end portion on the second cathode 12 side. Based on the above findings, in the present embodiment, the protrusion is formed on the inner wall of the anode toward the central axis B in a range from a position equidistant from both end portions of the anode to the end portion facing the first cathode. Accordingly, in the present embodiment, both the electron concentration point and the ion emission position can be shifted further toward the first cathode 11 than in the comparative embodiments, and a significantly larger amount of ions can be emitted from the ion emission range that is larger than those in the comparative embodiments. Accordingly, the amount of ions colliding with components inside the ion gun can be reduced at the same time.

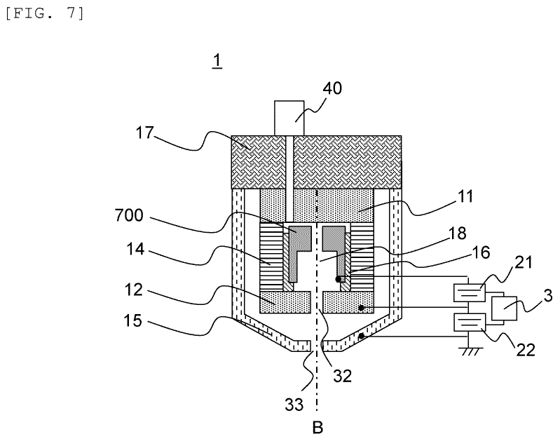

FIG. 6 is a diagram illustrating a cross section of an ion gun and a configuration of a related peripheral portion according to an embodiment (Embodiment 1). An anode 600 is made of a non-magnetic material having conductivity such as aluminum. In the present embodiment, the anode 600 has a cylindrical shape whose longitudinal direction is the direction along the central axis B of the ion generation unit, and has a protrusion formed on an inner surface of the anode 600 in contact with the ionization chamber 18 toward the central axis B at an end portion facing the first cathode 11, and an inner diameter of a portion where the protrusion is formed is narrowed. For example, an inner diameter of an end portion of the anode 600 facing the second cathode 12 is 6 mm, which is larger than a diameter (5 mm) of the cathode outlet hole 32 in the second cathode 12. On the other hand, a protrusion having, for example, a width of 1 mm and a height of 1 mm is formed toward the central axis B of the ion generation unit at the end portion facing the first cathode 11, and accordingly, the inner diameter of the portion where the protrusion is formed is 4 mm. Here, a size in the direction along the central axis B of the ion generation unit is referred to as a width, and a size in a direction orthogonal to the central axis B is referred to as a height.

FIG. 7 is a diagram illustrating a cross section of an ion gun and a configuration of a related peripheral portion according to another embodiment (Embodiment 2). An anode 700 is made of a non-magnetic material having conductivity such as aluminum. In the present embodiment, the anode 700 has a cylindrical shape whose longitudinal direction is the direction along the central axis B of the ion generation unit, and has a protrusion formed on an inner surface of the anode 700 in contact with the ionization chamber 18 toward the central axis B at an end portion facing the first cathode 11, and an inner diameter of a portion where the protrusion is formed is narrowed. For example, an inner diameter of an end portion of the anode 700 facing the second cathode 12 is 8 mm, which is larger than the diameter (5 mm) of the cathode outlet hole 32 in the second cathode 12. On the other hand, a protrusion having, for example, a width of 3 mm and a height of 1 mm is formed toward the central axis B of the ion generation unit at the end portion facing the first cathode 11, and accordingly, the inner diameter of the portion where the protrusion is formed is 4 mm.

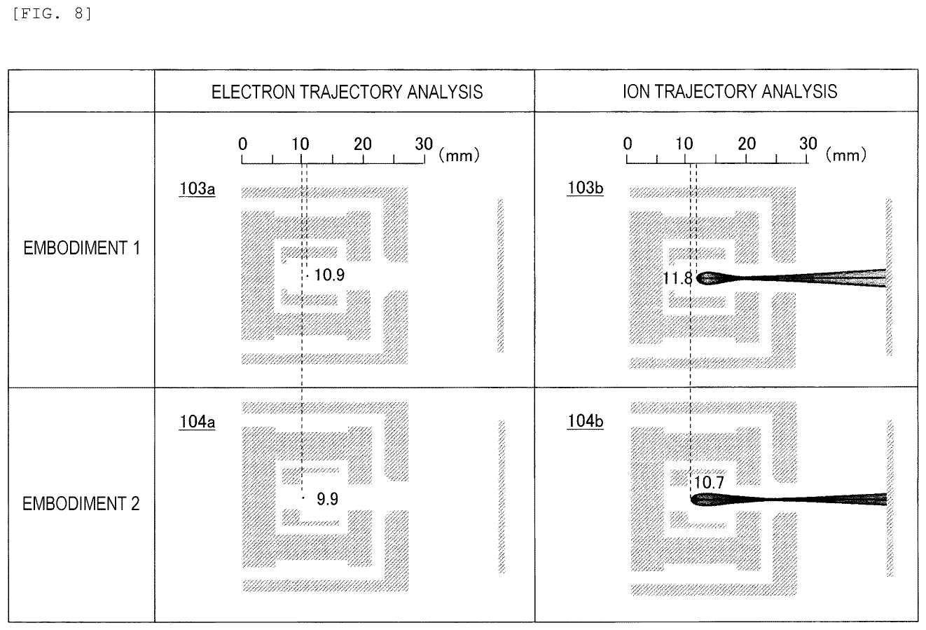

FIG. 8 is a diagram illustrating electron trajectory analysis results and ion trajectory analysis results of the ion guns according to the embodiments. Embodiment 1 is an ion gun having the anode shape illustrated in FIG. 6, and analysis results of Embodiment 1 are analysis results 103a and 103b. Embodiment 2 is an ion gun having the anode shape illustrated in FIG. 7, and analysis results of Embodiment 2 are analysis results 104a and 104b. For comparison, a simulation is performed in the same manner as in the analysis illustrated in FIG. 4, except for the anode shape.

It is illustrated that the electron concentration point is located at a distance of 10.9 mm from the bottom surface of the first cathode in the analysis result 103a according to Embodiment 1, and is located at a distance of 9.9 mm from the bottom surface of the first cathode in the analysis result 104a according to Embodiment 2. The analysis result 103b according to Embodiment 1 shows that ions generated in a region closer to the second cathode 12 at a distance of 11.8 mm from the bottom surface of the first cathode are emitted to the outside, and the analysis result 104b according to Embodiment 2 shows that ions generated in a region closer to the second cathode 12 at a distance of 10.7 mm from the bottom surface of the first cathode are emitted to the outside.

Thus, in both Embodiment 1 and Embodiment 2, the electron concentration point and the deepest portion of the ion emission position are shifted further toward the first cathode 11 than in the comparative embodiments, a significantly larger amount of ions can be emitted from the ion emission range that is larger than that in the comparative embodiments, and a milling speed can be higher than that in the comparative embodiments. At the same time, in the comparative embodiments, the ions colliding with the first cathode 11 are emitted to the outside, so that the damage to the first cathode 11 can be reduced, and a maintenance cycle can be lengthened.

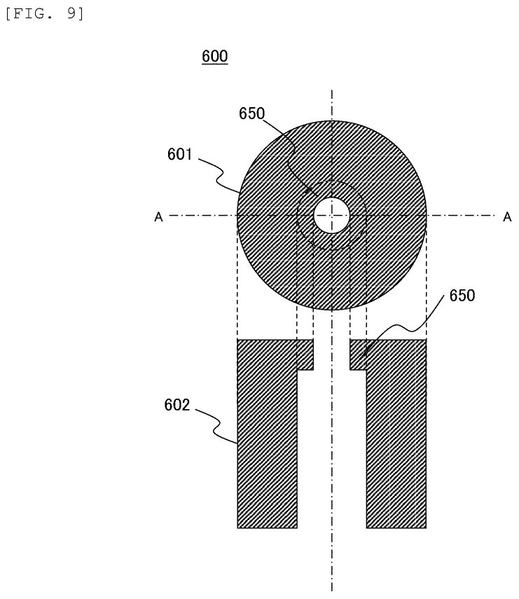

FIG. 9 illustrates an example of the anode 600 according to the embodiment. A plan view 601 and a cross-sectional view 602 taken along a line AA are illustrated. A protrusion 650 having a width of 1 mm and a height of 1 mm is formed toward the central axis B of the ion generation unit at the end portion of the anode 600 facing the first cathode 11. The protrusion 650 makes the inner diameter of the end portion of the anode 600 facing the first cathode 11 smaller than the inner diameter of the end portion of the anode 600 facing the second cathode 12. In the example in FIG. 9, the protrusion 650 is continuously formed in a circumferential shape. The example in Embodiment 1 is illustrated, and the protrusion in Embodiment 2 can also be formed in the same manner.

FIG. 10 illustrates another example of the anode 600 according to the embodiment. A plan view 603 and a cross-sectional view 604 taken along the line AA are illustrated. In the example in FIG. 10, a protrusion 660 includes a plurality of protrusions formed circumferential shape at a predetermined interval. The protrusion provided on the anode 600 narrows the inner diameter of the anode 600, and thus becomes an obstacle to the introduction of the Ar gas and the electron into the ionization chamber 18. Therefore, it is easier to introduce the Ar gas and the electron into the ionization chamber 18 by forming the protrusions provided on the anode 600 discontinuously in the circumferential shape as illustrated in FIG. 10 than by forming the protrusion continuously in the circumferential shape. The example in Embodiment 1 is illustrated, and the protrusion in Embodiment 2 can also be formed in the same manner.

Modifications of the ion gun according to the embodiment are illustrated below.

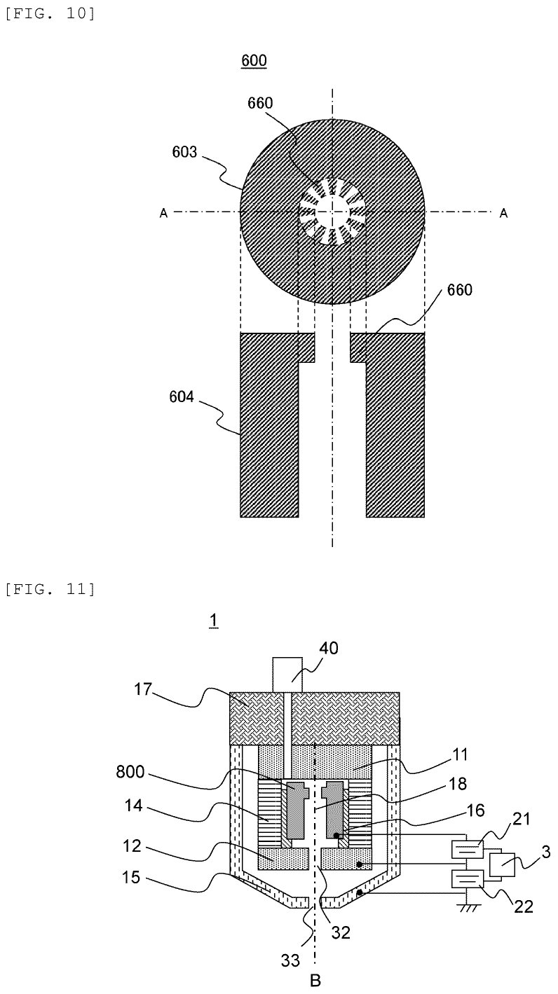

FIG. 11 is a diagram illustrating a cross section of an ion gun and a configuration of a related peripheral portion according to an embodiment (Modification 1). An anode 800 is made of a non-magnetic material having conductivity such as aluminum. In Modification 1, the anode 800 (having a length of 9.5 mm) has a cylindrical shape whose longitudinal direction is the direction along the central axis B of the ion generation unit, and has a protrusion formed on an inner surface of the anode 800 in contact with the ionization chamber 18 toward the central axis B at a position 2 mm away from an end portion facing the first cathode 11, and an inner diameter of a portion where the protrusion is formed is narrowed. For example, an inner diameter of an end portion of the anode 800 facing the second cathode 12 is 6 mm, which is larger than the diameter (5 mm) of the cathode outlet hole 32 in the second cathode 12, while the inner diameter of the portion where the protrusion is formed is 4 mm.

A manufacturing process of the anode 800 is more complicated than manufacturing processes of the anodes according to Embodiment 1 and Embodiment 2, but by providing the protrusion in a range from a position equidistant from both end portions of the anode 800 to the end portion facing the first cathode 11, an effect of shifting the electron concentration point and the ion emission position toward the first cathode 11 can be obtained.

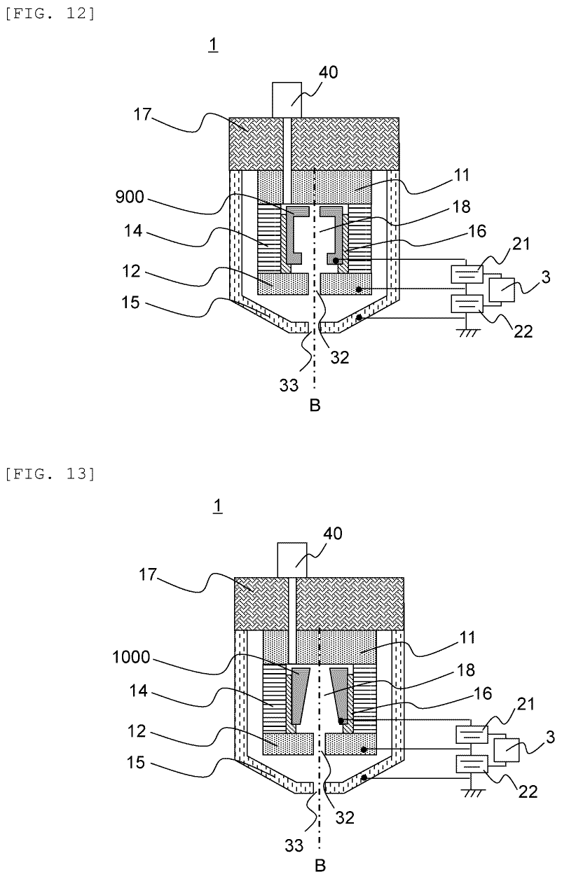

FIG. 12 is a diagram illustrating a cross section of an ion gun and a configuration of a related peripheral portion according to an embodiment (Modification 2). An anode 900 is made of a non-magnetic material having conductivity such as aluminum. In Modification 2, the anode 900 has a cylindrical shape whose longitudinal direction is the direction along the central axis B of the ion generation unit, and has protrusions formed on an inner surface of the anode 900 in contact with the ionization chamber 18 toward the central axis B at both end portions, and inner diameters of portions where the protrusions are formed are narrowed. For example, when a height of a protrusion at the end portion facing the first cathode 11 is 1 mm, and a height of a protrusion at the end portion facing the second cathode 12 is 0.5 mm, in the anode 900, an inner diameter of a portion where no protrusion is provided is 6 mm, an inner diameter of the end portion facing the second cathode 12 is 5 mm, and an inner diameter of the end portion facing the first cathode 11 is 4 mm. Even if the protrusion is provided on a side facing the second cathode 12, the effect of shifting the electron concentration point and the ion emission position toward the first cathode 11 can be obtained by the protrusion provided on a side facing the first cathode 11 generating a strong potential gradient in the direction of the central axis B of the ion generation unit.

The shape of the protrusions in the above modifications may be a continuous shape in the circumferential shape as illustrated in FIG. 9, or may be a discontinuous shape in the circumferential shape as illustrated in FIG. 10.

FIG. 13 is a diagram illustrating a cross section of an ion gun and a configuration of a related peripheral portion according to an embodiment (Modification 3). An anode 1000 is made of a non-magnetic material having conductivity such as aluminum. In Modification 3, an inner diameter of an end portion of the anode 1000 facing the first cathode 11 is smaller than an inner diameter of an end portion facing the second cathode 12, and an inner wall of the anode 1000 is formed to continuously connect an opening at the end portion facing the first cathode 11 and an opening at the end portion facing the second cathode 12. As illustrated in FIG. 13, the openings may be connected such that a cross section of the inner wall taken along a plane including the central axis B of the ion generation unit is a straight line, or the openings may be connected such that the cross section of the inner wall is a curved line. The effect of shifting the electron concentration point and the ion emission position toward the first cathode 11 can also be obtained with such a shape.

Although the invention is specifically described based on the embodiments and the modifications, the invention is not limited to the embodiments and the modifications, and various modifications can be made without departing from the gist of the invention. It is also effective to apply the embodiments and the modifications in combination rather than alone.

### REFERENCE SIGNS LIST

1 ion gun
2 ion beam
3 ion gun controller
4 vacuum chamber
5 vacuum exhaust system
6 sample
7 sample stand
8 sample stage
9 sample stage driving unit
11 first cathode
12 second cathode
14 magnet
15 acceleration electrode
16 insulator
17 ion gun base
18 ionization chamber
21 discharge power supply
22 acceleration power supply
32 cathode outlet hole
33 acceleration electrode outlet hole
40 gas supply mechanism
101a, 101b, 102a, 102b, 103a, 103b, 104a, 104b analysis result
111, 112 beam mark
200 gas supply mechanism
201 gas source
500, 501, 600, 700, 800, 900, 1000 anode
601, 603 plan view
602, 604 cross-sectional view
650, 660 protrusion

1. An ion milling device comprising:
an ion gun that includes an ion generation unit and a gas supply mechanism configured to supply a gas to the ion generation unit, that accelerates an ion generated in the ion generation unit, and that emits the accelerated ion as an ion beam; and
a sample stage on which a sample to be irradiated with the ion beam from the ion gun is placed, wherein
the ion generation unit of the ion gun includes
a first cathode having a disk shape and a second cathode having a disk shape provided to face each other, the second cathode being provided with an ion beam extraction hole,
an anode provided between the first cathode and the second cathode in a state of being electrically insulated from the first cathode and the second cathode,
an ionization chamber that is surrounded by the first cathode, the second cathode, and the anode and to which the gas is supplied from the gas supply mechanism, and
a magnet configured to generate a magnetic field in the ionization chamber, and
the anode has a cylindrical shape whose longitudinal direction is a direction along a central axis of the ion generation unit, and has a first protrusion formed on an inner wall in contact with the ionization chamber toward the central axis in a range from a position equidistant from both end portions of the anode to the end portion facing the first cathode.

2. The ion milling device according to claim 1, wherein
the first protrusion of the anode is formed at the end portion facing the first cathode.

3. The ion milling device according to claim 1, wherein
on the inner wall of the anode in contact with the ionization chamber, a second protrusion is formed toward the central axis at the end portion facing the second cathode, and
a height of the first protrusion is larger than a height of the second protrusion.

4. The ion milling device according to claim 1, wherein
the first protrusion is continuously formed in a circumferential shape.

5. The ion milling device according to claim 1, wherein
the first protrusion includes a plurality of protrusions formed in a circumferential shape at a predetermined interval.

6. The ion milling device according to claim 1, wherein
an inner diameter of the end portion of the anode facing the second cathode is equal to or larger than a diameter of the ion beam extraction hole in the second cathode.

7. An ion milling device comprising:
an ion gun that includes an ion generation unit and a gas supply mechanism configured to supply a gas to the ion generation unit, that accelerates an ion generated in the ion generation unit, and that emits the accelerated ion as an ion beam; and
a sample stage on which a sample to be irradiated with the ion beam from the ion gun is placed, wherein
the ion generation unit of the ion gun includes
a first cathode having a disk shape and a second cathode having a disk shape provided to face each other, the second cathode being provided with an ion beam extraction hole,
an anode provided between the first cathode and the second cathode in a state of being electrically insulated from the first cathode and the second cathode,
an ionization chamber that is surrounded by the first cathode, the second cathode, and the anode and to which the gas is supplied from the gas supply mechanism, and
a magnet configured to generate a magnetic field in the ionization chamber, and
the anode has a cylindrical shape whose longitudinal direction is a direction along a central axis of the ion generation unit, and has an inner diameter of an end portion facing the first cathode smaller than an inner diameter of an end portion facing the second cathode, and an inner wall of the anode in contact with the ionization chamber is formed to continuously connect an opening at the end portion facing the first cathode and an opening at the end portion facing the second cathode.

8. The ion milling device according to claim 7, wherein
a cross section of the inner wall of the anode taken along a plane including the central axis is linear.

9. The ion milling device according to claim 7, wherein
the inner diameter of the end portion of the anode facing the second cathode is larger than a diameter of the ion beam extraction hole in the second cathode.

10. An ion milling method for processing a sample by using an ion milling device,
the ion milling device including a sample stage and an ion gun including an ion generation unit, an acceleration electrode, a discharge power supply, an acceleration power supply, and a gas supply mechanism,
the ion generation unit of the ion gun including a first cathode having a disk shape and a second cathode having a disk shape provided to face each other, the second cathode being provided with an ion beam.
